(19) United States
(12) Patent Application Publication
(10) Pub. No.: US 2026/0090242 A1
(43) Pub. Date: Mar. 26, 2026

(54) Backing Plates For Displays With Curved Surfaces

(71) Applicant: Apple Inc., Cupertino, CA (US)

(72) Inventors: Deokkyun Yoon, Milpitas, CA (US); Dongwoo Shin, San Jose, CA (US); Han-Chieh Chang, San Jose, CA (US); Jingjing Xu, Cupertino, CA (US); Kari Thorkelsson, Santa Clara, CA (US); Kentaro Shimizu, Sunnyvale, CA (US); Sabrina D Flemming, San Francisco, CA (US); Shubhaditya Majumdar, Santa Clara, CA (US); Ying-Chih Wang, Sunnyvale, CA (US)

(21) Appl. No.: 19/240,629

(22) Filed: Jun. 17, 2025

Related U.S. Application Data
(60) Provisional application No. 63/697,165, filed on Sep. 20, 2024.

(51) Int. Cl. H10K 59/80; H10K 59/12

(52) U.S. Cl. CPC H10K 59/873; H10K 59/1201

(57) ABSTRACT

An electronic device may have a display overlapped by a display cover layer. Portions of the surface of the display and cover layer may have curved profiles. For example, a display may have curved surface profiles including rounded corners having areas of compound curvature. To mitigate wrinkling in a flexible display panel molded to have compound curvature, a film may be included that absorbs force in the display panel. The film may be attached to the flexible display panel using an ultraviolet light curable adhesive. The display may also include a backing plate that conforms to the curvature of the flexible display panel. The backing plate may have slits and/or grooves to provide the backing plate with anisotropic effective moduli.

This application claims the benefit of U.S. provisional patent application No. 63/697,165, filed Sep. 20, 2024, which is hereby incorporated by reference herein in its entirety.

### FIELD

This relates generally to electronic devices, including electronic devices with displays.

### BACKGROUND

Electronic devices such as cellular telephones, tablet computers, and other electronic equipment may include displays for presenting images to a user.

If care is not taken, electronic devices with displays may not have a desired appearance or may be difficult to use satisfactorily. For example, displays may be bulky and unattractive or may not accommodate a desired electronic device shape.

### SUMMARY

An electronic device comprising a display panel having four rounded corner regions and four edge regions. Each one of the four edge regions may extend between a respective two of the four rounded corner regions, each one of the four edge regions may be bent, each one of the four rounded corner regions may have compound curvature, and the display panel may have upper and lower surfaces. The electronic device may also include a display cover layer that conforms to the upper surface of the display panel and a backing plate that conforms to the lower surface of the display panel. The backing plate may have four portions that overlap the four rounded corner regions and the backing plate may have a plurality of recesses in each one of the four portions.

An electronic device may have a display panel having first and second opposing edges connected by third and fourth opposing edges, wherein each one of the first, second, third, and fourth edges is bent, a display cover layer that overlaps the display panel, a backing film that conforms to a lower surface of the display panel, an adhesive layer that attaches the backing film to the lower surface of the display panel, and a backing plate that conforms to a lower surface of the backing film. The adhesive layer may have a storage modulus between 1 MPa and 900 MPa at 25 degrees Celsius, greater than 0.3 MPa at 65 degrees Celsius, and greater than 0.1 MPa at 85 degrees Celsius.

A method of forming a display with bent edges may include positioning an adhesive layer between a display panel for the display and a backing film, curing the adhesive layer by exposing the adhesive layer to ultraviolet light, attaching a display cover layer to the display panel, attaching a backing plate to the backing film, and bending the display panel, the backing film, the adhesive layer, and the backing plate to have the bent edges. Curing the adhesive layer may take less than 5 seconds.

### BRIEF DESCRIPTION OF THE DRAWINGS

FIG. 1 is a schematic diagram of an illustrative electronic device in accordance with some embodiments.

FIG. 2 is a top view of an illustrative electronic device in accordance with some embodiments.

FIG. 3 is a cross-sectional side view of an illustrative electronic device in accordance with some embodiments.

FIG. 4 is a cross-sectional side view of an illustrative planar portion of a display cover layer and pixel array in accordance with some embodiments.

FIG. 5 is a cross-sectional side view of an illustrative curved portion of a display cover layer and pixel array in accordance with some embodiments.

FIG. 6 is a cross-sectional side view of an illustrative sidewall portion of an electronic device in accordance with some embodiments.

FIG. 7 is a perspective view of an illustrative corner portion of an electronic device in accordance with some embodiments.

FIG. 8 is a cross-sectional side view of an illustrative display with bent edges in accordance with some embodiments.

FIG. 9 is a diagram of an illustrative method for forming the display of FIG. 8 using a two-stage bending process in accordance with some embodiments.

FIG. 10 is a diagram of an illustrative method for forming the display of FIG. 8 using a one-stage bending process in accordance with some embodiments.

FIG. 11 is a top view of an illustrative backing plate with patterned regions in accordance with some embodiments.

FIG. 12 is a top view of an illustrative backing plate with grooves that extend parallel to a perimeter of the backing plate and slits that extend orthogonal to the perimeter of the backing plate in accordance with some embodiments.

FIGS. 13A and 13B are cross-sectional side views of the illustrative backing plate of FIG. 12 in accordance with some embodiments.

FIG. 14 is a top view of an illustrative backing plate with slits that extend parallel to a perimeter of the backing plate in accordance with some embodiments.

FIG. 15 is a top view of an illustrative backing plate with slits in a rounded corner region that extend parallel to a perimeter of the backing plate and slits in the rounded corner region that extend orthogonal to the perimeter of the backing plate in accordance with some embodiments.

FIG. 16 is a top view of an illustrative backing plate with slits in edge regions that extend parallel to a perimeter of the backing plate and slits in a rounded corner region that extend orthogonal to the perimeter of the backing plate in accordance with some embodiments.

FIG. 17 is a top view of an illustrative backing plate with openings having footprints defined by four wavy edges in accordance with some embodiments.

FIG. 18 is a top view of an illustrative backing plate with openings having footprints defined by two convex edges and two concave edges in accordance with some embodiments.

FIG. 19 is a top view of an illustrative backing plate with openings having footprints defined by two circular portions and an intervening thinner bridging portion in accordance with some embodiments.

FIG. 20 is a top view of an illustrative backing plate with openings having oval footprints in accordance with some embodiments.

### DETAILED DESCRIPTION

Electronic devices may be provided with displays. The displays may have planar surfaces and curved surfaces. For example, a display may have a planar central portion surrounded by bent edges. The bent edges may have curved surface profiles. Arrangements in which displays exhibit compound curvature may also be used. Electronic devices having displays with curved surfaces may have an attractive appearance, may allow the displays to be viewed from a variety of different angles, and may include displays with a borderless or nearly borderless configuration.

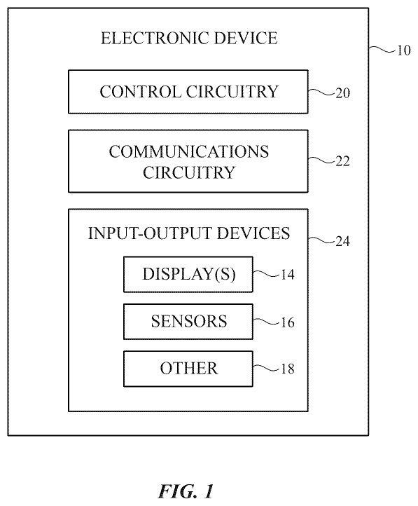

A schematic diagram of an illustrative electronic device having a display with curved surface portions is shown in FIG. 1. Device 10 may be a cellular telephone, a tablet computer, a laptop computer, a wristwatch device, a head-mounted device, or other wearable device, a television, a stand-alone computer display or other monitor, a computer display with an embedded computer (e.g., a desktop computer), a system embedded in a vehicle, kiosk, or other embedded electronic device, a media player, or other electronic equipment.

Device 10 may include control circuitry 20. Control circuitry 20 may include storage and processing circuitry for supporting the operation of device 10. The storage and processing circuitry may include storage such as nonvolatile memory (e.g., flash memory or other electrically-programmable-read-only memory configured to form a solid state drive), volatile memory (e.g., static or dynamic random-access-memory), etc. Processing circuitry in control circuitry 20 may be used to gather input from sensors and other input devices and may be used to control output devices. The processing circuitry may be based on one or more microprocessors, microcontrollers, digital signal processors, baseband processors and other wireless communications circuits, power management units, audio chips, application specific integrated circuits, etc.

To support communications between device 10 and external equipment, control circuitry 20 may communicate using communications circuitry 22. Circuitry 22 may include antennas, radio-frequency transceiver circuitry, and other wireless communications circuitry and/or wired communications circuitry. Circuitry 22, which may sometimes be referred to as control circuitry and/or control and communications circuitry, may support bidirectional wireless communications between device 10 and external equipment over a wireless link (e.g., circuitry 22 may include radio-frequency transceiver circuitry such as wireless local area network transceiver circuitry configured to support communications over a wireless local area network link, near-field communications transceiver circuitry configured to support communications over a near-field communications link, cellular telephone transceiver circuitry configured to support communications over a cellular telephone link, or transceiver circuitry configured to support communications over any other suitable wired or wireless communications link). Wireless communications may, for example, be supported over a Bluetooth® link, a WiFi® link, a 60 GHz link or other millimeter wave link, a cellular telephone link, or other wireless communications link. Device 10 may, if desired, include power circuits for transmitting and/or receiving wired and/or wireless power and may include batteries or other energy storage devices. For example, device 10 may include a coil and rectifier to receive wireless power that is provided to circuitry in device 10.

Device 10 may include input-output devices such as devices 24. Input-output devices 24 may be used in gathering user input, in gathering information on the environment surrounding the user, and/or in providing a user with output. During operation, control circuitry 20 may use sensors and other input devices in devices 24 to gather input and can control output devices in devices 24 to provide desired output.

Devices 24 may include one or more displays such as display(s) 14. An output device such as display 14 may be an organic light-emitting diode (OLED) display, a liquid crystal display, an electrophoretic display, an electrowetting display, a plasma display, a microelectromechanical systems display, a display having a pixel array formed from crystalline semiconductor light-emitting diode dies (sometimes referred to as microLEDs), and/or other display. Display 14 may have an array of pixels configured to display images for a user. The display pixels may be formed on a substrate such as a flexible substrate (e.g., display 14 may be formed from a flexible display panel). Conductive electrodes for a capacitive touch sensor in display 14 and/or an array of indium tin oxide electrodes or other transparent conductive electrodes overlapping display 14 may be used to form a two-dimensional capacitive touch sensor for display 14 (e.g., display 14 may be a touch sensitive display).

Sensors 16 in input-output devices 24 may include force sensors (e.g., strain gauges, capacitive force sensors, resistive force sensors, etc.), audio sensors such as microphones, touch and/or proximity sensors such as capacitive sensors (e.g., a two-dimensional capacitive touch sensor integrated into display 14, a two-dimensional capacitive touch sensor overlapping display 14, and/or a touch sensor that forms a button, trackpad, or other input device not associated with a display), and other sensors. If desired, sensors 16 may include optical sensors such as optical sensors that emit and detect light, ultrasonic sensors, optical touch sensors, optical proximity sensors, and/or other touch sensors and/or proximity sensors, monochromatic and color ambient light sensors, image sensors, fingerprint sensors, temperature sensors, sensors for measuring three-dimensional non-contact gestures (“air gestures”), pressure sensors, sensors for detecting position, orientation, and/or motion (e.g., accelerometers, magnetic sensors such as compass sensors, gyroscopes, and/or inertial measurement units that contain some or all of these sensors), health sensors, radio-frequency sensors, depth sensors (e.g., structured light sensors and/or depth sensors based on stereo imaging devices), optical sensors such as self-mixing sensors and light detection and ranging (lidar) sensors that gather time-of-flight measurements, humidity sensors, moisture sensors, gaze tracking sensors, and/or other sensors. In some arrangements, device 10 may use sensors 16 and/or other input-output devices to gather user input (e.g., buttons may be used to gather button press input, touch sensors overlapping displays can be used for gathering user touch screen input, touch pads may be used in gathering touch input, microphones may be used for gathering audio input, accelerometers may be used in monitoring when a finger contacts an input surface and may therefore be used to gather finger press input, etc.).

If desired, electronic device 10 may include additional components (see, e.g., other devices 18 in input-output devices 24). The additional components may include haptic output devices, audio output devices such as speakers, light producing output devices such as light-emitting diodes for status indicators, light sources such as light-emitting diodes (e.g., crystalline semiconductor light-emitting diodes) that illuminate portions of a housing and/or display structure, other optical output devices, and/or other circuitry for gathering input and/or providing output. Device 10 may also include a battery or other energy storage device, connector ports for supporting wired communication with ancillary equipment and for receiving wired power, and other circuitry.

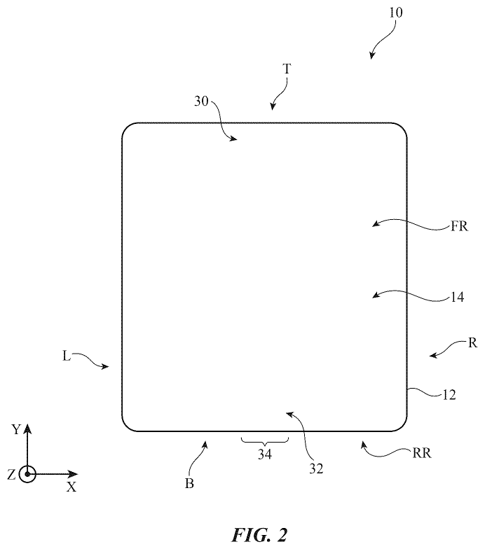

FIG. 2 is a front (plan) view of electronic device 10 in an illustrative configuration in which display 14 covers some or all of the front face FR of device 10. Opposing rear face RR of device 10 may be covered by a housing wall formed from glass, metal, polymer, and/or other materials. Rear face RR may be free of display pixels and/or may be partly or fully covered by display 14.

Device 10 may include a housing (e.g., housing 12) that forms sidewall structures for device 10 and/or internal supporting structures (e.g., a frame, midplate member, etc.). In some illustrative arrangements, sidewall portions of device 10 may be covered with portions of display 14. In the example of FIG. 2, device 10 is characterized by four peripheral edges: upper edge T, lower edge B, left edge L, and right edge R. Upper edge T and opposing lower edge B may run parallel to each other and parallel to the X axis of FIG. 2. Left edge L and opposing right edge R may run parallel to each other and parallel to the Y axis of FIG. 2. Front face FR and rear face RR may be planar (e.g., two parallel planes offset by a distance along the Z axis) and/or may include curved portions.

Touch sensor circuitry such as two-dimensional capacitive touch sensor circuitry may be incorporated into one or more display panels in device 10 as separate touch sensor panels overlapping display pixels or may be formed as part of one or more display panels in device 10. Touch sensors may be formed on front face FR, rear face RR, and/or edges (sidewall faces) T, B, R, and/or L. If desired, icons and other images for virtual buttons may be displayed by the pixels of device. For example, virtual buttons and/or other images may be displayed on front face FR, rear face RR, and/or sidewall structures in device 10 such as edges T, B, R, and/or L and may overlap touch sensor circuitry. Haptic output devices may be used to provide haptic feedback when virtual buttons are selected (as an example).

Device 10 of FIG. 2 has a rectangular outline with four rounded corners. If desired, device 10 may have other shapes. For example, device 10 may have a shape that folds and unfolds along a bend (folding) axis and may include a display that overlaps or that does not overlap the bend axis, may have a shape with an oval footprint or circular outline, may have a cubic shape, may have a pyramidal, cylindrical, or conical shape, or may have other suitable shapes. The configuration of FIG. 2 is illustrative.

If desired, openings may be formed in the surfaces of device 10. For example, a speaker port and optical windows for an ambient light sensor, an infrared proximity sensor, and a depth sensor may be formed in a region such as upper region 30 of front face FR. A finger print sensor, touch sensor button, force-sensitive button, or other sensor that operates through display 14 may be formed under the portion of display in lower region 32 on front face FR and/or other portions of front face FR and/or other external surfaces of device 10. An optional opening for a connector (e.g., a digital data connector, analog signal connector, and/or power connector) may be formed in portion 34 of the lower sidewall of device 10 running along lower edge B. This opening may be omitted when power is received wirelessly or is received through contacts that are flush with the surface of device 10 and/or when data is transferred and received wirelessly using wireless communications circuitry in circuitry 22 or through contacts that are flush with the exterior surface of device 10.

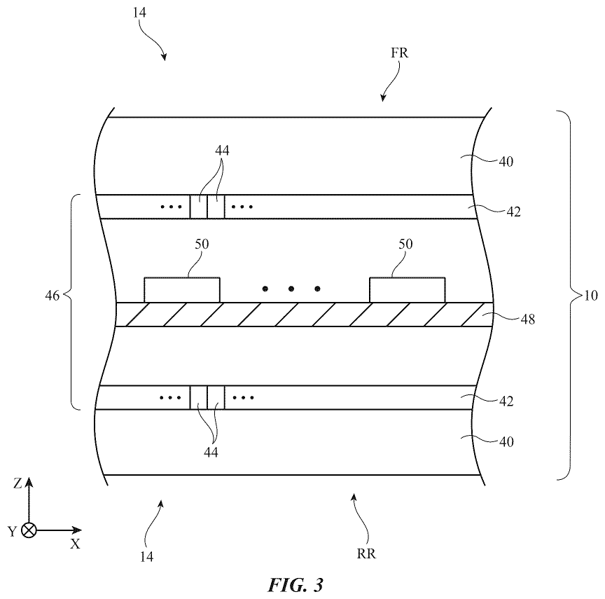

FIG. 3 is a cross-sectional side view of an illustrative electronic device. As shown in FIG. 3, display 14 may be formed on front face FR and/or rear face RR of device 10. Display 14 may include one or more transparent protective layers such as display cover layer 40. Display cover layer 40 may be formed from transparent material such as clear glass, polymer, sapphire or other crystalline material, or other transparent material. Display layers such as layers 42 may have arrays of pixels 44 that form images. The pixel arrays (e.g., layers 42) may sometimes be referred to as pixel layers, pixel array layers, displays, display structures, display layers, or display panels. For example, layers 42 may be formed from organic light-emitting diode displays. In the example of FIG. 3, device 10 has a first display 14 (or first display portion of a display panel or other display structure) formed from a first pixel array 42 on front face FR. This first pixel array is visible in the −Z direction through display cover layer 40 on front face FR. Device 10 of FIG. 3 also has a second display 14 (or second display portion of the display panel or other display structure) formed from a second pixel array 42 on rear face RF. This second pixel array is visible in the +Z direction through display cover layer 40 on rear face RR. The front and/or rear surfaces formed by display cover layer(s) 40 may be planar (as shown in FIG. 3) or may have a curved profile.

If desired, the second display 14 of device 10 may be omitted. For example, pixel array 42 on rear face RR may be omitted. In this configuration, the inner surface of layer 40 on rear face RR may be coated with a black masking material or other opaque coating and/or may be coated with colored and/or shiny structures. Coating material can be patterned to form logos, text, and other visual elements. This type of arrangement may be used to hide internal components in interior 46 of device from view from the exterior of device 10. As shown in FIG. 3, for example, device 10 may include electrical components 50 in interior 46 (e.g., integrated circuits, sensors and other input-output devices, control circuitry, display layers 42 such as organic light-emitting diode panels or other display layers, etc.). Electrical components 50 may, if desired, be mounted on printed circuits such as printed circuit 48 (e.g., flexible printed circuits and/or printed circuits formed from rigid printed circuit board material). In configurations such as these in which the lower pixel array of device 10 is omitted, the portion of device 10 on rear face RR (e.g., layer 40) may be formed from metal (e.g., a stainless steel or aluminum layer). For example, device 10 may have a rear housing wall formed from metal. Device 10 may also have housing walls formed from opaque glass, transparent glass coated with opaque materials such as ink or metal, and/or other housing wall materials.

In some configurations for device 10, an opaque material such as metal or opaque polymer may form some or all of the sidewalls of device 10. As an example, metal that forms some or all of a rear housing wall on rear face RR of device 10 may protrude upwardly along the edges of device 10 to form some or all of the sidewalls for device 10. As another example, a peripheral metal band that forms some or all of the sidewalls of device 10 may extend around the rectangular periphery of device 10 (e.g., along upper edge T, right edge R, lower edge B, and left edge L). Sidewalls may have vertically extending planar surfaces and/or may exhibit other surface profiles (e.g., curved profiles).

If desired, some or all of the sidewalls of device 10 may be formed from clear material and may overlap light-producing components. This material may, as an example, be part of display cover layers 40 of FIG. 3 (e.g., an extending piece of glass, polymer, crystalline material, or other transparent display cover layer material). Because clear layers of glass, plastic, crystalline material, and/or other clear layers of material in device 10 may enclose and protect internal device components, these outer layers of material in device 10 serve as an enclosure (housing 12) for device 10.

In configurations for device 10 in which sidewalls have transparent portions formed from extending portions of display cover layers 40 or other transparent material, the sidewalls may overlap light-emitting components. Transparent sidewalls may have planar and/or curved surfaces and may be formed from clear glass, clear polymer, transparent crystalline material such as sapphire, and/or other transparent protective material. Displays (pixel arrays), light-emitting diodes covered with diffusing material, light-emitting diodes covered with patterned masks (e.g., opaque coatings with icon-shaped openings or openings of other shapes), and/or other light-emitting devices may be placed under clear sidewalls.

During operation, light emitted from the pixels or other light-emitting components under the sidewalls may pass through the sidewalls. In arrangements in which display panels are placed under transparent sidewalls, images may be displayed through the sidewalls. The images may form parts of images being displayed on front face FR and/or rear face RR and/or may be separate images. For example, a photograph may extend across front face FR and some or all of the sidewalls of device 10 and/or a photograph may cover only front face FR while virtual buttons are displayed on the sidewalls of device 10. In arrangements in which one or more light-emitting diodes and an overlapping diffuser are placed under transparent sidewalls, diffuse light may be emitted through the sidewalls.

In addition to optional opaque housing structures such as metal housing walls or opaque walls formed from other materials, device 10 may include display cover layers 40 and other structures formed from transparent glass, transparent polymer, and/or other transparent material. These materials may surround the interior of device 10 and thereby serve as a housing for device 10 as well as serving as protective layers for pixel arrays and other light-emitting components. In the example of FIG. 3, the front surface of device 10 is formed by a planar surface of display cover layer 40 on front face FR and the rear surface of device 10 is formed by a planar surface of display cover layer 40 on rear face RR. In general, device 10 may have planar surface portions and/or curved surface portions (surface portions with curved profiles) and these portions may be formed by display cover layers, other layers formed from glass, polymer, sapphire or other crystalline material, ceramic, or other potentially transparent materials, metal, wood, or other materials.

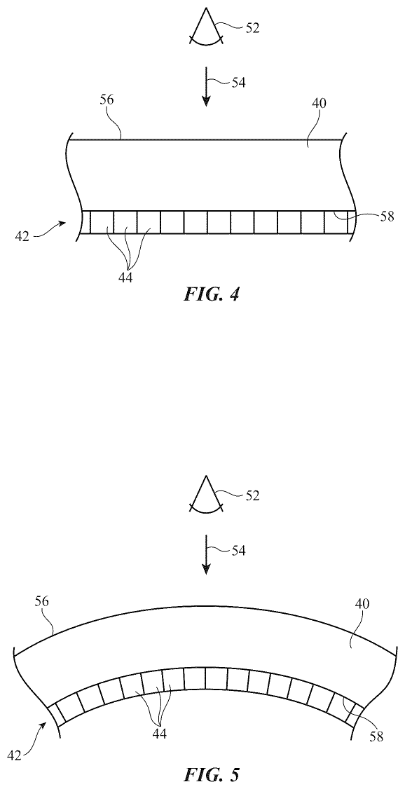

Transparent portions of device 10 may overlap pixels or other light-emitting components that emit light that is visible to a user. In the illustrative arrangements of FIGS. 4 and 5, an array of pixels 44 in layer 42 is configured to emit light that passes through display cover layer 40 for viewing by viewer 52 (e.g., in direction 54 and/or other directions from the exterior of device 10). The inner and outer surface of layers 40 (and other layers enclosing the interior of device 10) may be planar and/or curved. In the illustrative configuration of FIG. 4, outer surface 56 of layer 40 and inner surface 58 of layer 40 are planar. Inner surface 58 of FIG. 4 may be curved or partly planar and partly curved, if desired. In the illustrative configuration of FIG. 5, outer surface 56 of layer 40 is curved and inner surface 58 of layer 40 is curved. Inner surface 58 may, if desired, be planar or may have planar and curved surface profile portions.

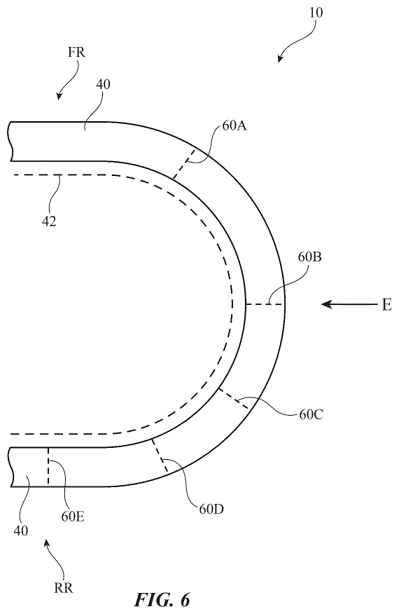

Device 10 may have upper and/or lower surfaces (e.g., external surfaces 56 on front face FR and rear face RR, respectively) that are planar and/or curved. The edges of device 10 may have sidewalls with planar and/or curved portions (e.g., surfaces with straight and/or curved profiles). As shown in FIG. 6, for example, the sidewalls of device 10 along one or more edges such as edge E of device 10 (e.g., left edge L, right edge R, upper edge T, lower edge B, and/or the corners of device 10) may have a curved outer surface.

Edge E may be transparent (e.g., the entire sidewall of device 10 may be transparent and may be formed from extended portions of upper and lower display cover layer(s)) and/or one or more portions of the curved sidewall of edge E may be opaque (e.g., formed from glass or other material that is coated with opaque material, formed from opaque polymer, formed from metal, and/or formed from other opaque structures). Opaque structures (e.g., metal housing wall portions) may extend along one or more portions of edge E (e.g., metal or other opaque material may form the portion of edge E between locations 60A and 60B, between locations 60B and 60C, between locations 60C and 60D, between locations 60D and 60E, between locations 60A and 60C, between locations 60B and 60D, between locations 60C and 60E, or between other suitable locations on edge E). There may be a single strip of metal housing material that runs around all four peripheral edges E of device 10, there may be a pair of discrete strips of metal housing material that run around all four peripheral edges E in parallel, there may be no non-glass structures on edges E, and/or there may be other suitable structures on edges E.

Display layer 42 may be formed from a single panel (e.g., a single flexible organic light-emitting diode display panel having a polyimide substrate or other flexible substrate with bent edge portions), may be formed from multiple panels (e.g., multiple panels separated from one or more gaps), may be formed from panels with slits and other openings, and/or may be formed from other types of displays. Portions of display layer 42 (e.g., all of layer 42 and/or the pixels and/or other structures of layer 42) may be omitted wherever layer 42 is overlapped by a metal portion of edge E and/or other opaque structures in edge E. For example, edge E may be formed from glass everywhere except between locations 60B and 60D. The portion of edge (sidewall) E between locations 60B and 60D may be formed from metal (as an example). In this type of scenario, no display layer 42 (or at least no pixels 44) may be overlapped by the metal and pixels 44 and display layer 42 may be present under the glass portions of edge E and/or display cover layer 40 on front face FR and/or rear face RR.

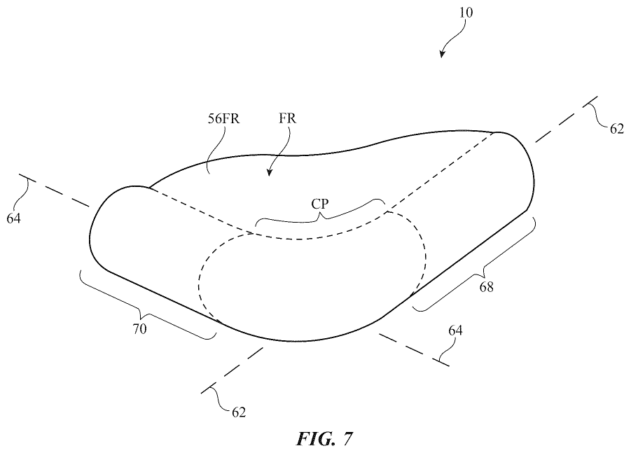

If desired, device 10 may have external surfaces with compound curvature. A perspective view of an illustrative corner portion of device 10 is shown in FIG. 7. In the example of FIG. 7, device 10 has edge portions (sidewalls) 68 and 70 with surfaces that curve about axes 62 and 64, respectively. These portions extend along the straight sides of device 10 and are characterized by curved surfaces that can be flattened into a plane without distortion (sometimes referred to as developable surfaces). At the corner of device 10, device 10 has curved surface portions CP with compound curvature (e.g., a surface that can only be flattened into a plane with distortion, sometimes referred to as a surface with Gaussian curvature). Each of the four corners of device 10 may have this arrangement, if desired.

Flexible displays such as organic light-emitting diode displays with flexible polyimide substrates or other bendable polymer substrates can be bent about axes such as axes 62 and 64 to form curved surfaces in portions 68 and 70. In compound curvature regions such as corner regions of device 10, display 14 can be formed from materials that stretch (e.g., displays formed from mesh-shaped elastomeric substrate material), may be formed from flexible displays that are patterned to create flexible strips and other structures that can be bent to cover at least part of the compound curvature regions, and/or may use optical structures (e.g., lenses, etc.) to redirect light emitted from pixels in a display to surfaces with compound curvature.

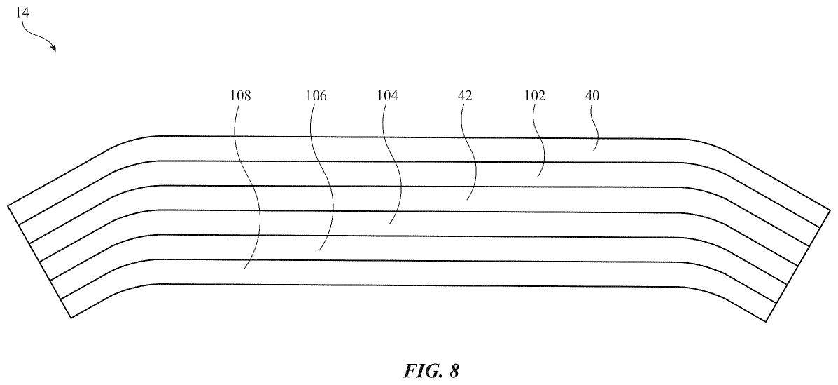

FIG. 8 is a cross-sectional side view of an illustrative display with bent edges. As shown in FIG. 8 pixel array 42 (sometimes referred to as display panel 42) is overlapped by display cover layer 40. An adhesive layer such as adhesive layer 102 may be interposed between display panel 42 and display cover layer 40. Adhesive layer 102 may be an optically clear adhesive layer. Display cover layer 40 and adhesive layer 102 may each have a transparency that is greater than 80%, greater than 90%, greater than 95%, greater than 98%, etc.

In addition to display cover layer 40, display panel 42 may also be attached to a backing film and/or backing plate. In the example of FIG. 8, display 42 is attached to backing film 106 and backing plate 108. An adhesive layer 104 is interposed between display panel 42 and backing film 106. Because adhesive layer 104, backing film 106, and backing plate 108 are positioned beneath display panel 42, each one of adhesive layer 104, backing film 106, and backing plate 108 may be transparent or opaque.

Backing film 106 may absorb strains in the flexible display panel to mitigate wrinkling and/or cracking in a flexible display panel molded to have compound curvature. Backing film 106 may be formed from any desired material and may have a Young's modulus magnitude (in GPa) greater than 0.1, greater than 0.5, greater than 1, greater than 2, greater than 3, greater than 5, greater than 8, greater than 10, less than 10, less than 5, less than 3, less than 2, less than 1, less than 0.5, between 0.5 and 5, between 0.1 and 10, between 0.5 and 3, etc.

Backing plate 108, meanwhile, may be formed from a relatively high hardness material and increases the mechanical strength of display 14. Backing plate 108 may be formed from stainless steel, titanium, carbon fiber reinforced plastic (CFRP), aluminum, copper, or another desired material. Backing plate 108 may be formed from a material having a Young's modulus magnitude (in GPa) greater than 10 GPa, greater than 50 GPa, greater than 100 GPa, greater than 150 GPa, greater than 200 GPa, between 100 GPa and 250 GPa, etc.

The display of FIG. 8 may have the footprint shown in FIG. 2. The display of FIG. 8 may have bends along the top, bottom, left, and right edges shown in FIG. 2. The display of FIG. 8 may have compound curvature (as shown in FIG. 7) in each one of the four rounded corners of the display.

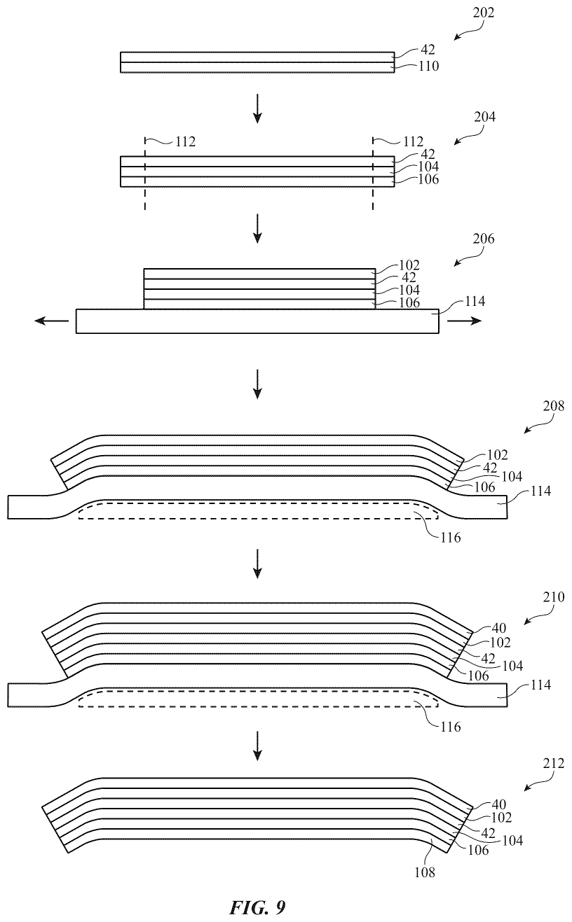

FIG. 9 is a diagram of an illustrative method for forming the display of FIG. 8. At step 202, display panel 42 may initially be attached to a temporary guide film 110. At step 204, the temporary guide film 110 may be removed and display panel 42 may be laminated to backing film 106 using adhesive layer 104. To attach display panel 42 to backing film 106 using adhesive layer 104, the adhesive layer 104 may be placed between display 42 and backing film 106. The adhesive layer 104 may then be cured to attach display panel 42 to backing film 106. Also during step 204, the edges of display panel 42, adhesive layer 104, and/or backing film 106 may optionally be trimmed by cutting along scribe lines 112.

At step 206, backing film 106, adhesive layer 104, and display panel 42 may be attached to guide film 114. Additionally, optically clear adhesive layer 102 may be attached to an upper surface of display panel 42. At step 206, guide film 114 may optionally be stretched (e.g., pulled outwards radially) to stretch guide film 114. Stretching guide film 114 may cause corresponding stretching in backing film 106, adhesive layer 104, display panel 42, and/or adhesive layer 102.

At step 208, while guide film 114 is optionally being stretched, guide film 114 may be pressed into a mold 116 that has desired curvature. Mold 116 may have curvature that imparts the desired bends to display 14 when the display is pressed into the mold. As shown in FIG. 9, pressing the display and guide film 114 into mold 116 may cause backing film 106, adhesive layer 104, display 42, and adhesive layer 102 to be bent into a target shape for the display.

At step 210, display cover layer 40 may be laminated to display panel 42. The display cover layer may be pressed into contact with adhesive layer 102 to attach the display cover layer to display panel 42. The display cover layer may have a target curvature (that matches the curvature of display 14) before laminating the display cover layer onto the display. Display cover layer 40 and the other display layers may be pressed into mold 116 during step 210.

At step 212, backing plate 108 may be attached to the lower surface of backing film 106. A layer of adhesive may optionally be included between backing plate 108 and backing film 106. In some cases, backing plate 108 may be bent into a target shape (e.g., with curvature matching the curvature of display 14) before being attached to display 14. However, this may result in unintended mismatch between the curvature profile of backing plate 108 and the curvature profile of the other display layers (e.g., due to manufacturing tolerance for the backing plate).

To mitigate mismatch between the curvature profile of backing plate 108 and the curvature profile of the other display layers, a planar backing plate 108 may be pressed into a lower surface of backing film 106 to conform to the curvature of backing film 106 (and the overlying layers). After the planar backing plate is pressed into backing film 106, the backing plate may have the curvature shown in FIG. 9.

It is noted that the display may be heated during one or more of steps 206, 208, and 210. Heating the display layers while stretching backing film 106 may create panel precompression that mitigates warping/wrinkling in display panel 42. Additional details regarding techniques for manufacturing displays with curved surfaces using backing films are described in U.S. application Ser. No. 18/184,552, filed Mar. 15, 2023, which is hereby incorporated by reference in its entirety.

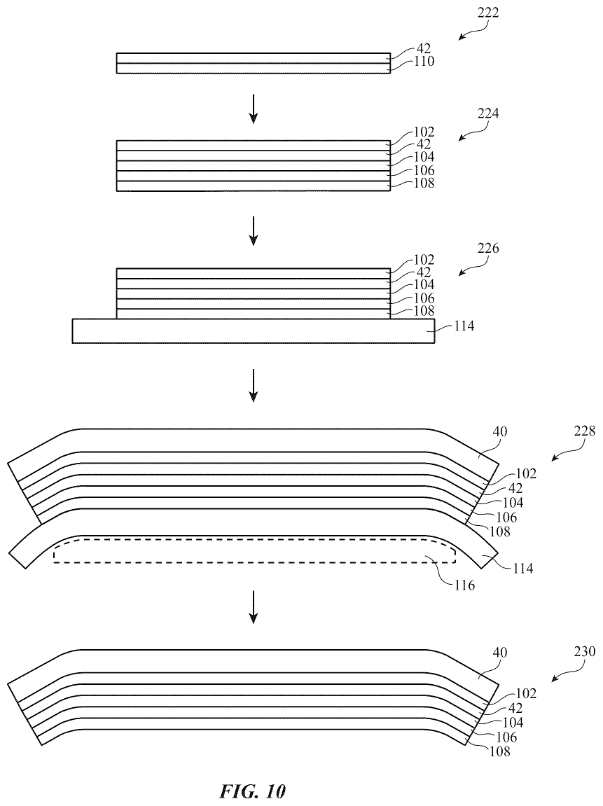

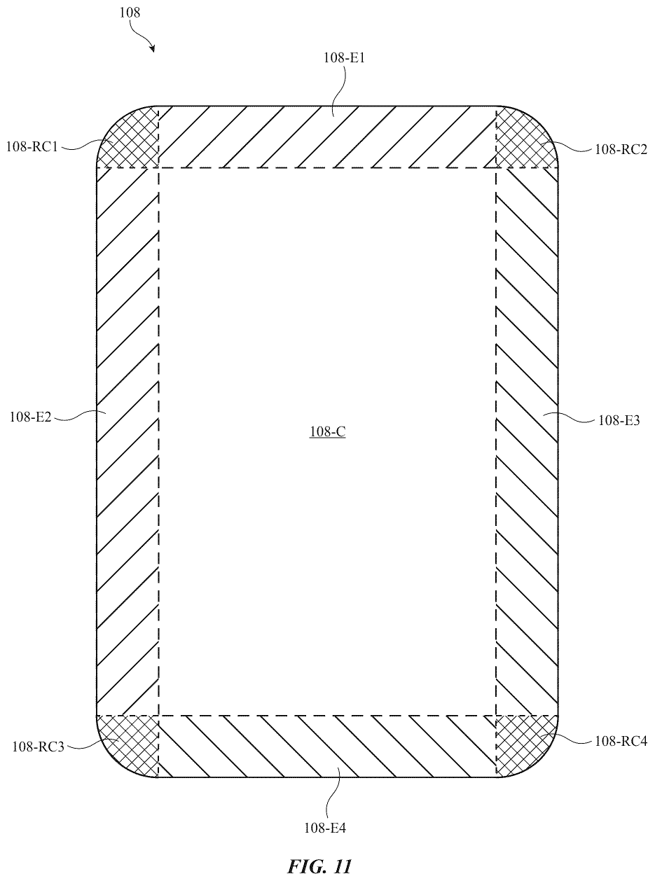

In the method of FIG. 9, backing plate 108 is bent into a target curved shape at a different time than layers 102, 42, 104, and 106. This example (which may be referred to as a two-stage bending process) is merely illustrative. In another possible arrangement (sometimes referred to as a one-stage bending process), backing plate 108 may be bent in parallel with layers 102, 42, 104, and 106. FIG. 10 is a diagram of a one-stage bending process.

At step 222, display panel 42 may initially be attached to a temporary guide film 110. At step 224, the temporary guide film 110 may be removed and display panel 42 may be laminated to backing film 106 using adhesive layer 104. To attach display panel 42 to backing film 106 using adhesive layer 104, the adhesive layer 104 may be placed between display 42 and backing film 106. The adhesive layer 104 may then be cured to attach display panel 42 to backing film 106. Also during step 224, backing plate 108 may be attached to the lower surface of backing film 106 and optically clear adhesive layer 102 may be attached to an upper surface of display panel 42. A layer of adhesive may optionally be included between backing plate 108 and backing film 106. During step 224, the edges of one or more of adhesive layer 102, display panel 42, adhesive layer 104, backing film 106, and backing plate 108 may optionally be trimmed (similar to as shown and discussed in connection with step 204 of FIG. 9).

At step 226, backing plate 108 may be attached to guide film 114. Then, during step 228, display cover layer 40 may be laminated to display panel 42. The display cover layer may be pressed into contact with adhesive layer 102 to attach the display cover layer to display panel 42. The display cover layer may have a target curvature (that matches the curvature of display 14) before laminating the display cover layer onto the display. Display cover layer 40 and the other display layers may be pressed into mold 116 during step 228.

Mold 116 may have curvature that imparts the desired bends to display 14 when the display is pressed into the mold. As shown in FIG. 10, pressing the display into mold 116 may cause backing plate 108, backing film 106, adhesive layer 104, display 42, and adhesive layer 102 to be bent into a target shape for the display. After the display cover layer is laminated to the display and the display has been bent to conform to mold 116, guide film 114 may be removed at step 230.

It is noted that backing film 106 may optionally be stretched and/or heated during one or more of the steps of FIG. 10, similar to as previously discussed in connection with FIG. 9.

To improve the robustness of display 14 and mitigate the time required to manufacture display 14, it may be desirable for adhesive layer 104 between backing film 106 and display panel 104 to be fast curing, have high adhesion strength, have a high modulus, and have a high temperature resistance. Adhesive layer 104 may comprise acrylic and/or polyurethane. The adhesive layer may be cured by exposure to ultraviolet light (e.g., light with a wavelength between 100 nanometers and 400 nanometers, between 315 and 400 nanometers, between 365 nanometers and 405 nanometers, etc.). Adhesive layer 104 may therefore sometimes be referred to as UV curable adhesive. Adhesive layer 104 may have a cure time of less than 30 seconds, less than 20 seconds, less than 10 seconds, less than 5 seconds, less than 3 seconds, between 1 second and 10 seconds, etc. A fast cure time for adhesive layer 104 may improve throughput when manufacturing displays of this type during mass production.

Adhesive layer 104 may have (after curing) a storage modulus between 1 MPa and 900 MPa at 25 degrees Celsius, between 100 MPa and 900 MPa at 25 degrees Celsius, greater than 500 MPa at 25 degrees Celsius, greater than 700 MPa at 25 degrees Celsius, etc. Adhesive layer 104 may have (after curing) a storage modulus that is greater than 0.3 MPa at 65 degrees Celsius, greater than 1 MPa at 65 degrees Celsius, greater than 5 MPa at 65 degrees Celsius, greater than 10 MPa at 65 degrees Celsius, etc. Adhesive layer 104 may have (after curing) a storage modulus that is greater than 1 MPa at 85 degrees Celsius, greater than 0.5 MPa at 85 degrees Celsius, greater than 0.1 MPa at 85 degrees Celsius.

As previously discussed, backing plate 108 may be formed from stainless steel, titanium, carbon fiber reinforced plastic (CFRP), aluminum, copper, or another desired material. In some cases, backing plate 108 may be a planar sheet of material with a target footprint. However, when the backing plate 108 is a planar sheet of material without any patterning, the backing plate exhibits isotropic effective moduli in all directions. Isotropic effective moduli may cause difficulties in bending the backing plate into desired shapes (e.g., compound curvature at the rounded corners) and/or may impart undesired strain onto display panel 42 when the backing plate is attached to the display.

To mitigate issues caused by isotropic effective moduli in the backing plate, the backing plate may be patterned with one or more slits and/or grooves. The slits and/or grooves may cause the backing plate to have anisotropic effective moduli.

FIG. 11 is a top view of an illustrative backing plate with one or more patterned regions. The patterned regions may have anisotropic effective moduli. The patterned regions may improve the case with which the backing plate may be bent into a desired shape. As shown in FIG. 11, backing plate 108 may have a rectangular shape with rounded corners. The backing plate has four rounded corner regions 108-RC1, 108-RC2, 108-RC3, and 108-RC4 and four edge regions 108-E1, 108-E2, 108-E3, and 108-E4. Each edge region is interposed between two respective rounded corner regions.

Backing plate 108 may be patterned to have anisotropic effective moduli in each one of rounded corner regions 108-RC1, 108-RC2, 108-RC3, and 108-RC4. In some cases, backing plate 108 may only be patterned in rounded corner regions 108-RC1, 108-RC2, 108-RC3, and 108-RC4. In other words, the backing plate may have openings and/or a varying thickness in rounded corner regions 108-RC1, 108-RC2, 108-RC3, and 108-RC4 while the remainder of the backing plate (including the edge regions) may have a uniform thickness without openings.

In another possible arrangement, backing plate 108 may be patterned to have anisotropic effective moduli in each one of rounded corner regions 108-RC1, 108-RC2, 108-RC3, and 108-RC4 and in each one of edge regions 108-E1, 108-E2, 108-E3, and 108-E4. The remainder of the backing plate (sometimes referred to as central region 108-C) may have a uniform thickness without openings.

The patterning used in the patterned regions in backing plate 108 may be the same or may be different. For example, the same pattern of openings and/or varying thickness may be applied to all four rounded corner regions or different patterns of openings and/or varying thickness may be applied to different rounded corner regions. The same pattern of openings and/or varying thickness may be applied to all four edge regions or different patterns of openings and/or varying thickness may be applied to different edge regions. The edge regions may have different patterns of openings and/or varying thickness than the rounded corner regions or may have the same pattern of openings and/or varying thickness as the rounded corner regions.

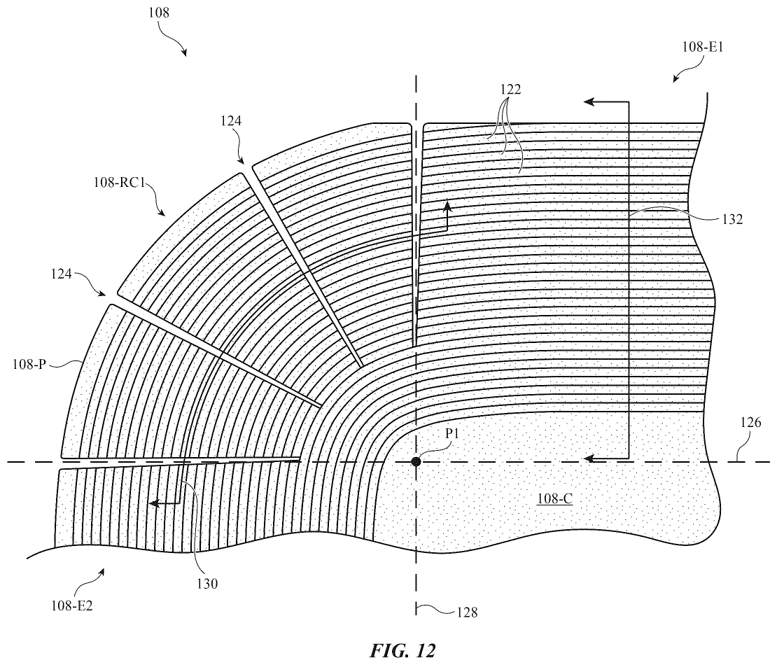

Examples of patterns of openings and/or varying thickness that may be used in backing plate 108 are shown in FIGS. 12-16. FIG. 12 is a top view of an illustrative backing plate with slits and grooves. The backing plate may be characterized by a perimeter 108-P that extends around the exterior footprint of the backing plate. The backing plate perimeter (sometimes referred to as backing plate edge) has a rectangular shape with four rounded corners. FIG. 12 shows an example where the backing plate has a plurality of grooves 122. The solid lines in FIG. 12 show the edges of the grooves.

In the example of FIG. 12, each groove extends parallel to backing plate perimeter 108-P. At any given point along the groove, the groove may be parallel to perimeter 108-P at the portion of the perimeter that is closest to that point along the groove. Edge portion 108-E1 of backing plate 108 extends from left to right along a top edge of the backing plate between rounded corner portions 108-RC1 and 108-RC2. Within edge portion 108-E1, the grooves 122 extend from left to right between rounded corner portions 108-RC1 and 108-RC2. In other words, the grooves 122 are parallel to the top edge of the display in top edge region 108-E1. Edge portion 108-E2 of backing plate 108, meanwhile, extends from top to bottom along a left edge of the backing plate between rounded corner portions 108-RC1 and 108-RC3. Within edge portion 108-E2, the grooves 122 extend from top to bottom between rounded corner portions 108-RC1 and 108-RC3. In other words, the grooves 122 are parallel to the left edge of the display in left edge region 108-E2. Within rounded corner portion 108-RC1, the grooves are curved such that grooves are parallel to the perimeter of the backing plate in rounded corner portion 108-RC1.

Grooves 122 may be formed in concentric rings that extend parallel to the perimeter of the backing plate. The grooves may therefore be parallel to one another.

FIG. 12 shows an example where backing plate 108 includes slits 124 in addition to grooves 122. Specifically, backing plate 108 in FIG. 12 includes four slits. Each slit may have a length and a width (with the length being at least 5 times greater than the width, at least 10 times greater than the width, at least 20 times greater than the width, at least 30 times greater than the width, etc.). The width of each slit may optionally increase with increasing distance from central portion 108-C (as shown in FIG. 12).

In FIG. 12, the slits may be arranged radially such that each slit extends from perimeter 108-P towards a reference point P1. Reference point P1 may define a border of the rounded corner region 108-RC1.

As an example, central portion 108-C of backing plate 108 may be planar (even after the backing plate is incorporated into a display with bends). The edge portions 108-E1, 108-E2, 108-E3, and 108-E4 are bent about one bend axis (after the backing plate is incorporated into a display with bends). The dashed line 126 in FIG. 12 marks the border between the central portion 108-C (without bending after the backing plate is incorporated into a display with bends) and edge portion 108-E1 (with bending about an axis parallel to dashed line 126 after the backing plate is incorporated into a display with bends). The dashed line 128 in FIG. 12 marks the border between the central portion 108-C (without bending after the backing plate is incorporated into a display with bends) and edge portion 108-E2 (with bending about an axis parallel to dashed line 128 after the backing plate is incorporated into a display with bends). Within rounded corner region 108-RC1, the backing plate has compound curvature and is bent about two axes (after the backing plate is incorporated into a display with bends). Reference point P1 may be the point at which borders 126 and 128 intersect.

Instead or in addition, each slit 124 may originate at a point along perimeter 108-P and may extend orthogonal to the perimeter from that point (e.g., towards central portion 108-C).

As shown in FIG. 12, each slit extends between a given point on perimeter 108-P and reference point P1. Slits 124 relieve compressive stress in a direction orthogonal to the slits and therefore may prevent buckling when rounded corner region 108-RC1 is bent to have compound curvature.

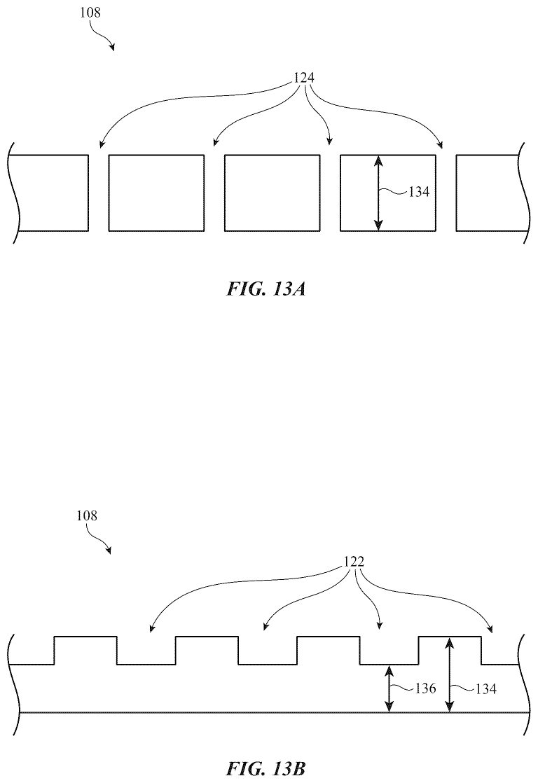

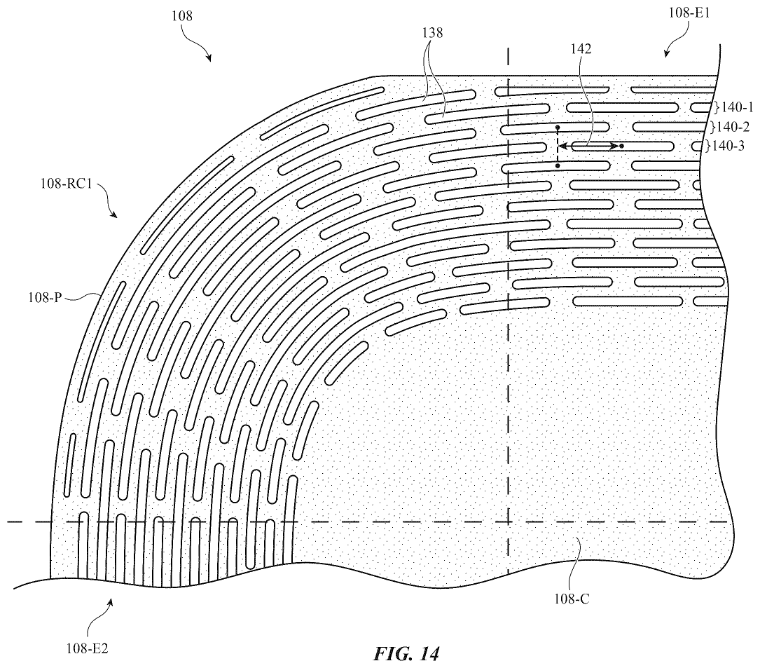

FIG. 13A is a cross-sectional side view taken along line 130 of FIG. 12. FIG. 13A shows how the backing plate may be completely removed in each slit 124. Herein, areas in which the backing plate is completely removed may be referred to as slits, slots, openings, recesses, etc. FIG. 13B is a cross-sectional side view taken along line 132 of FIG. 12. FIG. 13B shows how the backing plate may have a reduced thickness in grooves 122 relative to the remainder of the backing plate. Herein, areas in which the backing plate is partially but not completely removed may be referred to as grooves, indents, recesses, etc. Both the areas in which the backing plate is completely removed and areas in which the backing plate is partially but not completely removed may be referred to as recesses, patterned features, flexibility-enhancement structures, etc.

The bulk of the backing plate (e.g., the planar central portion 108-C) may have a uniform thickness 134. In FIG. 13A, the slits have a thickness of 0 because the backing plate is completely removed to define the slits. The remaining portion of the backing plate adjacent to the slits may have the bulk thickness 134. In FIG. 13B, the grooves have a thickness 136 that is greater than 0 but less than bulk thickness 134. In other words, the grooves are reduced thickness portions of backing plate 108.

Thickness 136 may be less than 95% of thickness 134, less than 90% of thickness 134, less than 80% of thickness 134, less than 70% of thickness 134, less than 60% of thickness 134, less than 50% of thickness 134, less than 30% of thickness 134, etc. There may be a step transition between thickness 134 and 136 (as in FIG. 13B) or a gradual transition in thickness between thickness 134 and 136.

In the example of FIG. 12, slits 122 extend orthogonal to the perimeter 108-P. FIG. 14 shows an alternate arrangement where slits 138 extend parallel to the perimeter 108-P. At any given point along the slit, the slit may be parallel to perimeter 108-P at the portion of the perimeter that is closest to that point along the slit. In FIG. 14, this pattern of slits 138 parallel to perimeter 108-P may be the same in edge portion 108-E1, rounded corner portion 108-RC1, and edge portion 108-E2.

FIG. 14 shows how the rows of slits may be staggered relative to one another. FIG. 14 shows rows of slits such as row 140-1, row 140-2, and row 140-3. As shown in FIG. 14, a center of a given slit in row 140-1 may be offset (in a direction parallel to perimeter 108-P) by a distance 142 from a center of the closest given slit in row 140-2. In contrast, the center of the given slit in row 140-1 is aligned with the center of a given slit in row 140-3. The centers of the slits in rows 140-1 and 140-3 are aligned in a direction orthogonal to perimeter 108-P. The pattern of slits 138 in FIG. 14 may sometimes be referred to as a lattice pattern.

Within rounded corner portion 108-R1, the length of the slits may increase with increasing separation from central portion 108-C. Similarly, the length of the slits may increase with decreasing separation from perimeter 108-P. In contrast, the length of the slits may be uniform with decreasing or increasing separation from perimeter 108-P in edge portions 108-E1 and 108-E2.

The backing plate may be totally removed for each slit in FIG. 14 (e.g., each slit has a thickness of 0 similar to as shown in FIG. 13A).

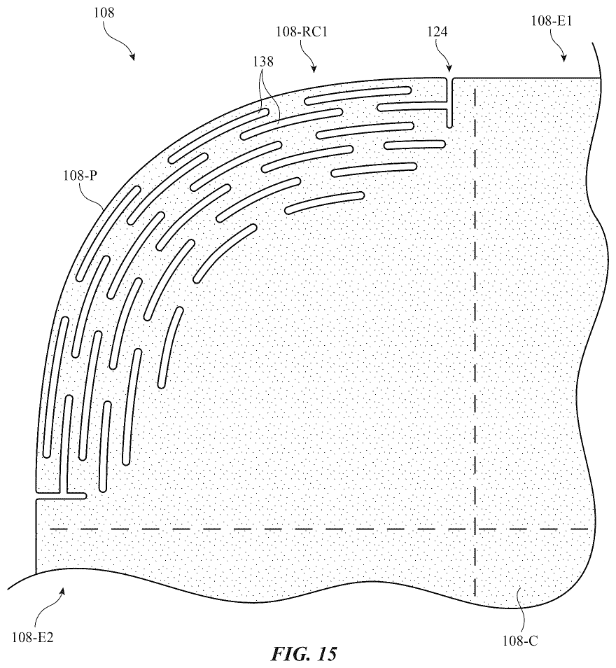

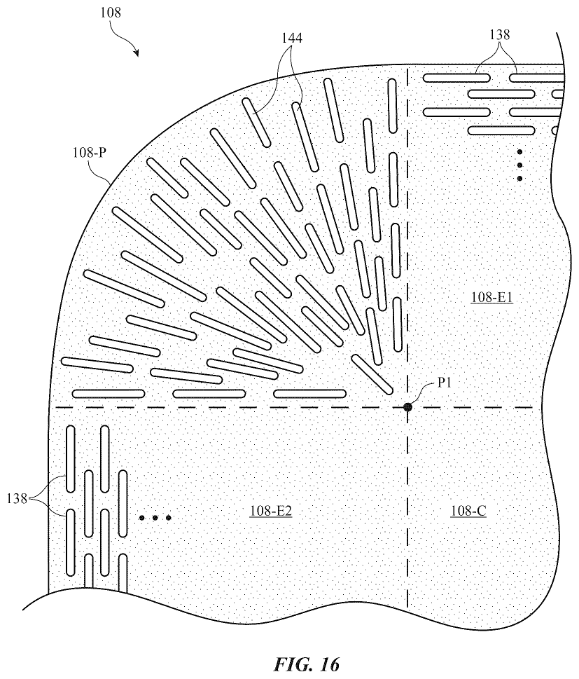

FIG. 15 shows another illustrative backing plate 108. In the example of FIG. 15, edge portions 108-E1 and 108-E2 are not patterned (and therefore have a uniform thickness throughout similar to central portion 108-C). Rounded corner portion 108-RC1, meanwhile, has both slits 124 that extend orthogonal to perimeter 108-P (similar to as in FIG. 12) and slits 138 that extend parallel to perimeter 108-P (similar to as in FIG. 14). In general, each one of the edge portions and rounded corner portions in backing plate 108 may include any desired combination of slits and grooves.

FIG. 16 shows an example where edge portions 108-E1 and 108-E2 of backing plate 108 have a different slit pattern than rounded corner portion 108-RC1 of backing plate 108. Edge portions 108-E1 and 108-E2 include slits 138 that extend parallel to perimeter 108-P (similar to as in FIG. 14). Rounded corner portion 108-RC1 includes slits 144 that extend orthogonal to perimeter 108-P. FIG. 12 shows another example with slits that extend orthogonal to perimeter 108-P. However, in FIG. 12 there is only one slit associated with each point along the perimeter having slits and each slit extends across the majority of rounded corner portion 108-RC1. In contrast, in FIG. 16 slits 144 have a similar lattice arrangement to the slits of FIGS. 14 and 15. In FIG. 16, parallel strips of two or more colinear slits 144 extend orthogonal to perimeter 108-P towards reference point P1.

Grooves 124 in FIG. 12 and slits 138 in FIGS. 14-16 may reduce radial stiffness of the backing plate in the regions of the backing plate where the recesses are present. Slits 124 in FIGS. 12 and 15 and slits 144 in FIG. 16 may relieve compressive stress in a direction orthogonal to the slits.

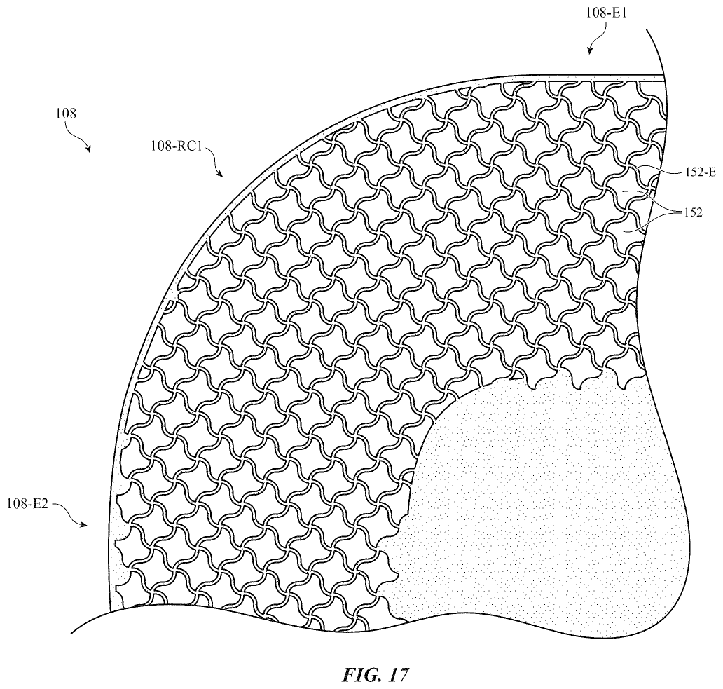

FIGS. 17-20 show examples where edge portions 108-E1 and 108-E2 of backing plate 108 have the same recess pattern as rounded corner portion 108-RC1 of backing plate 108. In each one of FIGS. 17-20, the white areas within backing plate 108 represent an opening in backing plate 108 (where the backing plate has been completely removed). The stippled areas within backing plate 108 represent the remaining portions of the backing plate. In each one of FIGS. 17-20, the patterned areas have a negative Poisson ratio. A negative Poisson ratio means that elongation of the patterned area in a first direction also causes elongation of the patterned area in a second, orthogonal direction. Similarly, compression of the patterned area in a first direction also causes compression of the patterned area in a second, orthogonal direction. The negative Poisson ratio pattern may extend in a ring around the entire perimeter of the backing plate.

In the example of FIG. 17, the backing plate comprises a plurality of openings 152. Each opening 152 may have a footprint defined by four edges 152-E. Each edge 152-E may have one or more curves and may be characterized as wavy. The four edges of the opening may be the same or may be different. In the example of FIG. 17, each edge 152-E has a sinusoidal shape with two curves. Each edge 152-E therefore has a shape similar to one period of a sinusoidal wave.

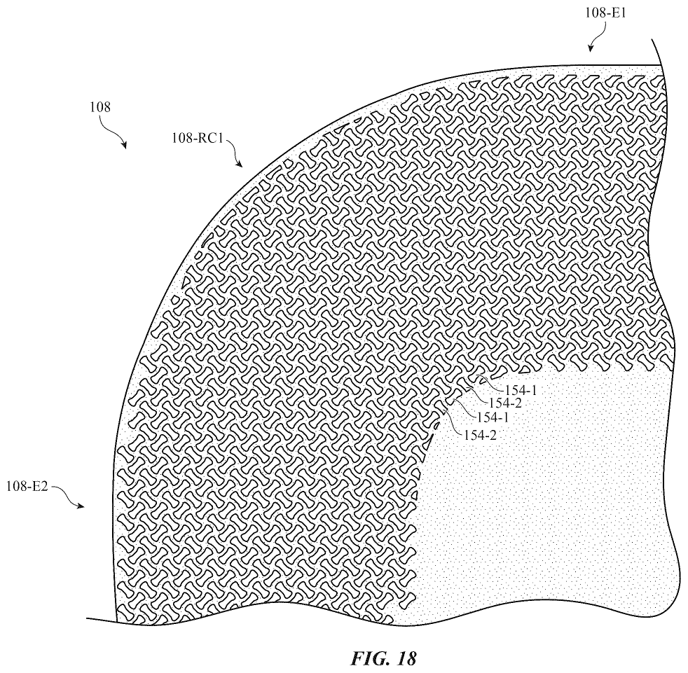

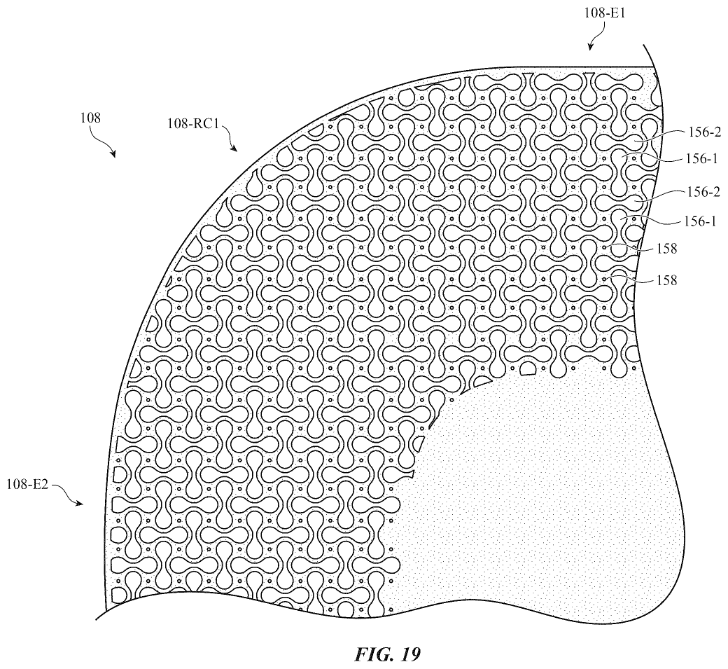

In the example of FIG. 18, the backing plate comprises a plurality of openings 154. Each opening may have first and second opposing edges and third and fourth opposing edges that connect the first and second opposing edges. The first and second opposing edges have convex curvature whereas the third and fourth opposing edges have concave curvature. The concave edges may be longer than the convex edges. The openings 154 have the same footprint but different orientations. The orientation of each opening may be characterized by an axis of symmetry for the opening. A first subset 154-1 of openings 154 are oriented at a first 45 degree angle relative to the top edge of the display and backing plate (e.g., edge 108-E1 in FIG. 18). A second subset 154-2 of openings 154 are oriented at a second 45 degree angle relative to the top edge of the display and backing plate (e.g., edge 108-E1 in FIG. 18). The orientation of the first subset 154-1 is orthogonal to the orientation of the second subset 154-2.

Openings 154 in FIG. 18 may be aligned such that each opening 154-1 is aligned with centers of first and second adjacent openings 154-2. Similarly, each opening 154-2 is aligned with centers of first and second adjacent openings 154-1.

In the example of FIG. 19, the backing plate comprises a plurality of openings 156. Each opening may have a peanut-shaped footprint with first and second circular portions connected by a bridging portion that is thinner than the first and second circular portions. The openings 156 have the same footprint but different orientations. The orientation of each opening may be characterized by an axis of symmetry for the opening. A first subset 156-1 of openings 156 are oriented at a 90 degree angle relative to the top edge of the display and backing plate (e.g., edge 108-E1 in FIG. 19). A second subset 156-2 of openings 156 are oriented at a 0 degree angle relative to the top edge of the display and backing plate (e.g., edge 108-E1 in FIG. 19). The orientation of the first subset 156-1 is orthogonal to the orientation of the second subset 156-2.

Openings 156 in FIG. 19 may be aligned such that each opening 156-1 is aligned with centers of first and second adjacent openings 156-2. Similarly, each opening 156-2 is aligned with centers of first and second adjacent openings 156-1.

FIG. 19 further shows how backing plate 108 may include additional openings 158. Each additional opening 158 may be interposed between first and second openings 156-2 above and below the opening 158, respectively. Each additional opening 158 may be interposed between first and second openings 156-1 to the left and right of the opening 158, respectively. The openings 158 may have circular footprints (as in FIG. 19), square footprints, or footprints of another desired shape. Openings 158 may be omitted if desired.

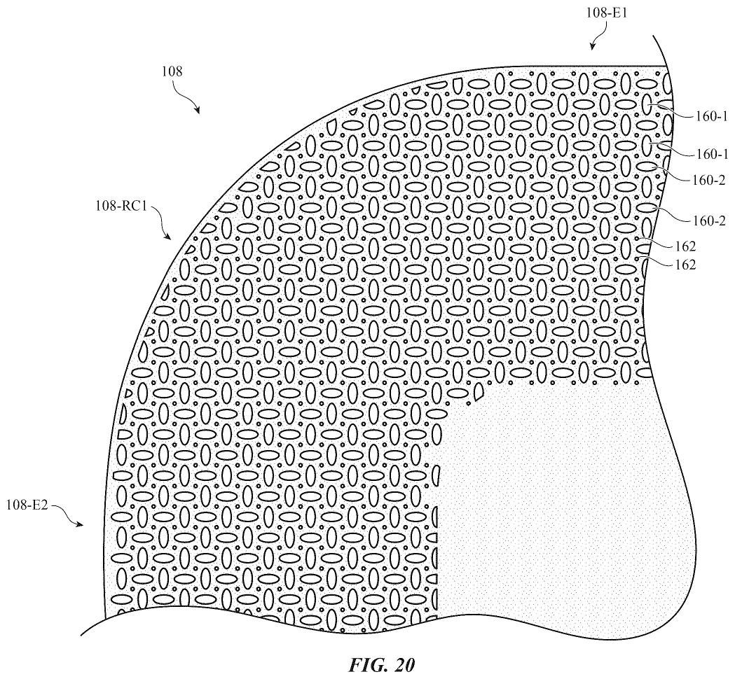

In the example of FIG. 20, the backing plate comprises a plurality of openings 160. Each opening may have an oval footprint. The openings 160 have the same footprint but different orientations. The orientation of each opening may be characterized by an axis of symmetry for the opening. A first subset 160-1 of openings 160 are oriented at a 90 degree angle relative to the top edge of the display and backing plate (e.g., edge 108-E1 in FIG. 20). A second subset 160-2 of openings 160 are oriented at a 0 degree angle relative to the top edge of the display and backing plate (e.g., edge 108-E1 in FIG. 20). The orientation of the first subset 160-1 is orthogonal to the orientation of the second subset 160-2.

Openings 160 in FIG. 20 may be aligned such that each opening 160-1 is aligned with centers of first and second adjacent openings 160-2. Similarly, each opening 160-2 is aligned with centers of first and second adjacent openings 160-1.

FIG. 20 further shows how backing plate may include additional openings 162. Each additional opening 162 may be interposed between first and second openings 160-2 above and below the opening 162, respectively. Each additional opening 162 may be interposed between first and second openings 160-1 to the left and right of the opening 162, respectively. The openings 162 may have circular footprints (as in FIG. 20), square footprints, or footprints of another desired shape. Openings 162 may be omitted if desired.

The foregoing is merely illustrative and various modifications can be made to the described embodiments. The foregoing embodiments may be implemented individually or in any combination.

What is claimed is:

1. An electronic device, comprising:
a display panel having four rounded corner regions and four edge regions, wherein each one of the four edge regions extends between a respective two of the four rounded corner regions, wherein each one of the four edge regions is bent, wherein each one of the four rounded corner regions has compound curvature, and wherein the display panel has upper and lower surfaces;
a display cover layer that conforms to the upper surface of the display panel; and
a backing plate that conforms to the lower surface of the display panel, wherein the backing plate has four portions that overlap the four rounded corner regions and wherein the backing plate has a plurality of recesses in each one of the four portions.

2. The electronic device defined in claim 1, wherein the backing plate has anisotropic effective moduli in each one of the four portions.

3. The electronic device defined in claim 1, wherein the backing plate has four additional portions that overlap the four edge regions and wherein the backing plate has an additional plurality of recesses in each one of the four additional portions.

4. The electronic device defined in claim 3, wherein the backing plate has anisotropic effective moduli in each one of the four portions and in each one of the four additional portions.

5. The electronic device defined in claim 3, wherein the display panel has a perimeter and wherein the additional plurality of recesses in the backing plate comprises a plurality of slits in the backing plate that extend parallel to the perimeter.

6. The electronic device defined in claim 3, wherein the display panel has a perimeter and wherein the additional plurality of recesses in the backing plate comprises a plurality of slits in the backing plate that extend orthogonal to the perimeter.

7. The electronic device defined in claim 1, wherein the display panel has a perimeter and wherein the plurality of recesses in the backing plate comprises a plurality of slits in the backing plate that extend parallel to the perimeter.

8. The electronic device defined in claim 1, wherein the display panel has a perimeter and wherein the plurality of recesses in the backing plate comprises a plurality of grooves in the backing plate that extend parallel to the perimeter.

9. The electronic device defined in claim 1, wherein the display panel has a perimeter and wherein the plurality of recesses in the backing plate comprises a plurality of slits in the backing plate that extend orthogonal to the perimeter.

10. The electronic device defined in claim 1, wherein each one of the plurality of recesses extends completely through the backing plate.

11. The electronic device defined in claim 1, wherein each one of the plurality of recesses extends only partially through the backing plate.

12. The electronic device defined in claim 1, further comprising:
a display cover layer that overlaps the display panel;
a backing film that is interposed between the display panel and the backing plate; and
an adhesive layer that is interposed between the backing film and the display panel.

13. The electronic device defined in claim 12, wherein the adhesive layer has a storage modulus between 1 MPa and 900 MPa at 25 degrees Celsius, greater than 0.3 MPa at 65 degrees Celsius, and greater than 0.1 MPa at 85 degrees Celsius.

14. The electronic device defined in claim 1, wherein the backing plate comprises a material selected from the group consisting of: stainless steel, titanium, and carbon fiber reinforced plastic.

15. The electronic device defined in claim 1, wherein the backing plate has a negative Poisson ratio in each one of the four portions.

16. An electronic device, comprising:
a display panel having first and second opposing edges connected by third and fourth opposing edges, wherein each one of the first, second, third, and fourth edges is bent;
a display cover layer that overlaps the display panel;
a backing film that conforms to a lower surface of the display panel;
an adhesive layer that attaches the backing film to the lower surface of the display panel, wherein the adhesive layer has a storage modulus between 1 MPa and 900 MPa at 25 degrees Celsius, greater than 0.3 MPa at 65 degrees Celsius, and greater than 0.1 MPa at 85 degrees Celsius; and
a backing plate that conforms to a lower surface of the backing film.

17. The electronic device defined in claim 16, wherein the display panel has four rounded corners with compound curvature.

18. The electronic device defined in claim 16, wherein the backing plate comprises a material selected from the group consisting of: stainless steel, titanium, and carbon fiber reinforced plastic.

19. A method of forming a display with bent edges, the method comprising:
positioning an adhesive layer between a display panel for the display and a backing film;
curing the adhesive layer by exposing the adhesive layer to ultraviolet light, wherein curing the adhesive layer takes less than 5 seconds;
attaching a display cover layer to the display panel;
attaching a backing plate to the backing film; and
bending the display panel, the backing film, the adhesive layer, and the backing plate to have the bent edges.

20. The method defined in claim 19, wherein, after the adhesive layer is cured, the adhesive layer has a storage modulus between 1 MPa and 900 MPa at 25 degrees Celsius, greater than 0.3 MPa at 65 degrees Celsius, and greater than 0.1 MPa at 85 degrees Celsius.

21. The method defined in claim 19, wherein the backing plate has four rounded corner regions and a plurality of recesses in each one of the four rounded corner regions.
